(19) United States
(12) Patent Application Publication
(10) Pub. No.: US 2019/0081612 A1
(43) Pub. Date: Mar. 14, 2019

(54) Signal Filtering Using Magnetic Coupling

(71) Applicant: Qualcomm Incorporated, San Diego, CA (US)

(72) Inventors: Rui Tang, San Diego, CA (US); Antonino Scuderi, San Diego, CA (US)

(21) Appl. No.: 15/699,984

(22) Filed: Sep. 8, 2017

(51) Int. Cl. H03H 9/54; H03H 9/05; H03H 1/00

(52) U.S. Cl. CPC H03H 9/542; H03H 2001/0021; H03H 1/0007; H03H 9/0542

(57) ABSTRACT

An apparatus is disclosed for signal filtering using magnetic coupling. The apparatus includes a substrate having an interface disposed on a surface of the substrate. The interface includes multiple connectors and is configured to accept a filter die that includes an acoustic resonator network. The apparatus also includes multiple inductors that are supported by the substrate. The multiple inductors are connected to the multiple connectors of the interface and are configured to generate a mutual inductance based on individual inductors of the multiple inductors.

### TECHNICAL FIELD

This disclosure relates generally to wireless devices and, more specifically, to band-pass filters that use at least two inductors that are magnetically coupled to generate a mutual inductance. This mutual inductance induces a compensation impedance to facilitate filtering with a passing frequency band.

### BACKGROUND

To improve data rates and network performance, current techniques enable a wireless device to simultaneously transmit and receive on separate frequency bands. The wireless device can include a multiplexer to enable signals of different frequency bands to be simultaneously transmitted and received via a shared antenna. This multiplexer typically employs multiple band-pass filter modules that can be individually tuned to different frequency bands. Each band-pass filter module enables communication signals within the tuned frequency band to pass with minimal attenuation (e.g., due to insertion loss) while rejecting (e.g., attenuating) signals at other frequency bands. Unfortunately, spurious signals generated by operations associated with one of the frequency bands can impact operation at another frequency band. For example, a harmonic of a low-frequency band uplink signal being emanated by a transmitter can decrease the sensitivity of a receiver that is receiving a mid-frequency band downlink signal. Consequently, the multiplexer becomes responsible for providing sufficient cross-isolation between the low-frequency band and the mid-frequency band. As additional frequency bands are supported by a given wireless device, it can be challenging to provide sufficient cross-isolation across the additional frequency bands.

### SUMMARY

An apparatus is disclosed that implements signal filtering using magnetic coupling. The magnetic coupling provides a compensation impedance that enables the apparatus to accommodate both insertion loss and cross-isolation performance specifications.

In an example aspect, an apparatus is disclosed. The apparatus includes a substrate having an interface disposed on a surface of the substrate. The interface includes multiple connectors and is configured to accept a filter die that includes an acoustic resonator network. The apparatus also includes multiple inductors that are supported by the substrate. The multiple inductors are connected to the multiple connectors of the interface and are configured to generate a mutual inductance based on individual inductors of the multiple inductors.

In an example aspect, an apparatus is disclosed. The apparatus includes a substrate having a surface. The apparatus also includes multiple inductors that are supported by the substrate. The multiple inductors are configured to generate a mutual inductance based on individual inductors of the multiple inductors. The apparatus further includes interface means for accepting, on a surface of the substrate, a filter die that includes an acoustic resonator network. In addition, the apparatus includes connection means for connecting the multiple inductors to the acoustic resonator network of the filter die.

In an example aspect, a method for signal filtering using magnetic coupling is disclosed. The method includes generating a mutual inductance with multiple inductors. The method also includes inducing, based on the mutual inductance, a compensation impedance that facilitates passing of a communication signal and attenuating of another signal. The method additionally includes passing the communication signal having a transmission frequency within a passing frequency band. The method further includes attenuating the other signal having a frequency within a suppression frequency band that is outside of the passing frequency band.

In an example aspect, an apparatus is disclosed. The apparatus includes a substrate having a surface. The apparatus also includes a filter die mounted to the surface of the substrate. The filter die has an acoustic resonator network that includes at least one series resonator and at least two shunt resonators. The acoustic resonator network is configured as a band-pass filter to provide a first amount of attenuation for a passing frequency band and a second amount of attenuation for a suppression frequency band that is outside the passing frequency band. The apparatus also includes at least two magnetically-coupled inductors that are supported by the substrate and connected to the two shunt resonators. The two magnetically-coupled inductors are configured to increase the second amount of attenuation for the suppression frequency band. The two magnetically-coupled inductors are further configured to induce a compensation impedance that is based on a mutual inductance of the two magnetically-coupled inductors.

### BRIEF DESCRIPTION OF DRAWINGS

FIG. 1 illustrates an example environment for signal filtering using magnetic coupling.

FIG. 2 illustrates an example band-pass filter module for signal filtering using magnetic coupling.

FIG. 3 illustrates graphs that characterize an example performance of an acoustic resonator network of the band-pass filter module.

FIG. 4 illustrates an example implementation of the band-pass filter module using series-connected inductors.

FIG. 5 illustrates an example implementation of the band-pass filter module using parallel-connected inductors.

FIG. 6 illustrates an example equivalent circuit of the band-pass filter module.

FIG. 7 illustrates graphs depicting example performance differences associated with non-magnetically coupled inductors and magnetically-coupled inductors of the band-pass filter module.

FIG. 8 illustrates an example implementation having two surface-mount inductors for signal filtering using magnetic coupling.

FIG. 9 illustrates an example implementation having one surface-mount inductor and one embedded inductor for signal filtering using magnetic coupling.

FIG. 10 illustrates an example implementation having two embedded inductors for signal filtering using magnetic coupling.

FIG. 11 is a flow diagram illustrating an example process for signal filtering using magnetic coupling.

### DETAILED DESCRIPTION

In some environments, a wireless device transmits a communication signal to a base station on an uplink (UL) and simultaneously receives another communication signal from the base station on a downlink (DL). For example, the wireless device can use frequency band 2 for the uplink (e.g., frequencies between 1850 and 1910 megahertz (MHz)) and frequency band 66 for the downlink (e.g., frequencies between 2110 and 2200 (MHz)). While generating the transmitted communication signal, a spurious signal (e.g., an undesirable signal) can be generated from non-linear components in the radio frequency front-end module, such as power amplifiers, switches, or filters. In general, the spurious signal has a spurious frequency outside of a transmitting frequency band (e.g., higher, lower, or a scalar multiple of the transmitting frequency). Furthermore, the spurious frequency may be within a receiving frequency band. Without sufficient rejection (e.g., attenuation) of the spurious signal, the spurious signal can cause interference with the received communication signal.

Because wireless devices can include multiple transmitters and receivers configured for different frequency bands, a multiplexer is typically used to enable the multiple transmitters and receivers to simultaneously transmit and receive through at least one shared antenna. The multiplexer can incorporate band-pass filter modules for each of the multiple transmitters and receivers. Each band-pass filter module is configured to pass signals having a frequency within a passing frequency band and attenuate signals having a frequency outside of the passing frequency band. In this way, a band-pass filter module can pass a transmitted communication signal while attenuating spurious signals having frequencies that fall outside the passing frequency band and within a frequency band of one receiver or within respective frequency bands of multiple receivers. The frequency bands for which the band-pass filter module is configured to reject are referred to herein as suppression frequency bands.

The band-pass filter module can include an acoustic resonator network to implement a band-pass filter. The acoustic resonator network can be tuned to provide minimal insertion loss (e.g., minimal attenuation) for the passing frequency band but may be unable to provide sufficient cross-isolation for the suppression frequency bands. Conventional techniques address this problem by adding non-magnetically coupled inductors to the acoustic resonator network. Although these inductors can provide additional attenuation at the suppression frequency bands, an insertion loss and bandwidth associated with the passing frequency band can be negatively impacted. For example, non-magnetically coupled inductors can decrease a bandwidth of the acoustic resonator network and cause increased insertion loss (and therefore degraded performance) of a communication signal in the passing frequency band. In general, conventional techniques are forced to sacrifice in-band insertion loss for out-of-band rejection, or vice versa.

In contrast with conventional approaches, example apparatuses are described herein for signal filtering using magnetic coupling. An apparatus includes a band-pass filter module having multiple magnetically-coupled inductors that are connected to an acoustic resonator network. The magnetic coupling of the inductors results in a mutual inductance that induces a compensation impedance that is in parallel with a portion of the acoustic resonator network. The compensation impedance enables the apparatus to provide minimal in-band insertion loss and sufficient out-of-band rejection so as to meet performance specifications. Example apparatuses that can implement signal filtering using magnetic coupling include radio frequency front-end (RFFE) modules, band-pass filters (BPF), multiplexers (e.g., quadplexers), and so forth.

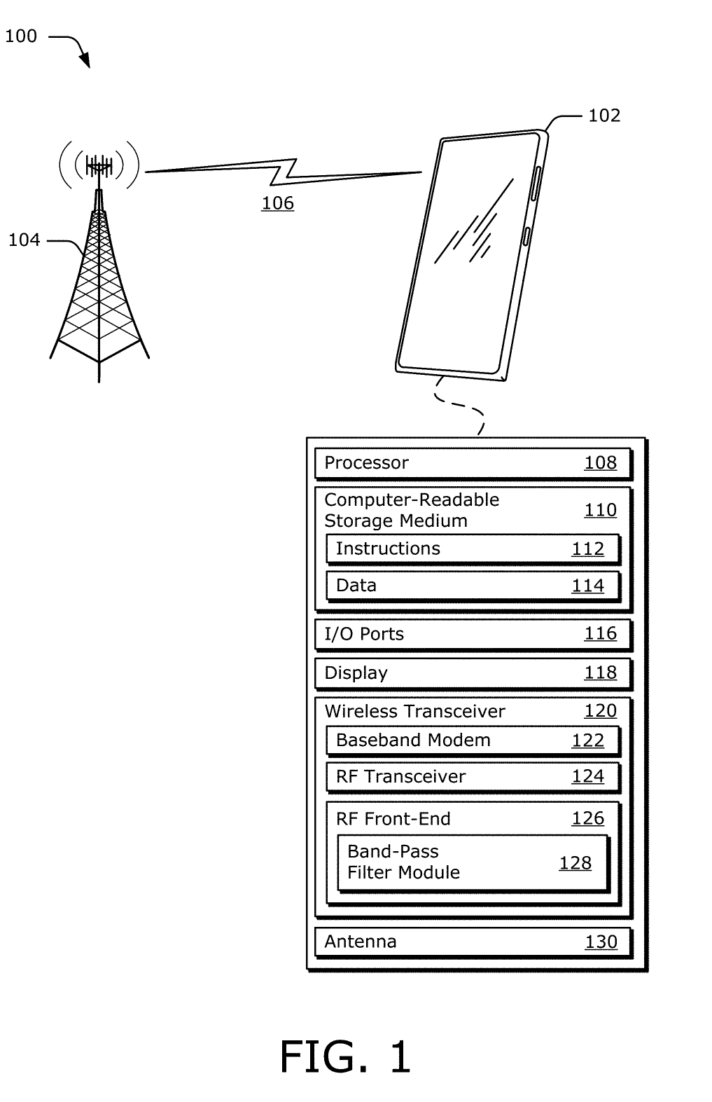

FIG. 1 illustrates an example environment 100, which includes a computing device 102 that communicates with a base station 104 through a wireless communication link 106 (wireless link 106). In this example, the computing device 102 is implemented as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device, via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

The computing device 102 includes a processor 108 and a computer-readable storage medium 110 (CRM 110). The processor 108 may include any type of processor, such as an application processor or multi-core processor, that is configured to execute processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) and a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternately or additionally, the display 118 may be implemented as a display port or virtual interface, through which graphical content of the computing device 102 is presented.

A wireless transceiver 120 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 120 may facilitate communication over any suitable type of wireless network, such as a wireless LAN (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith.

The wireless transceiver 120 includes at least one baseband modem 122, at least one radio frequency (RF) transceiver 124, and at least one RF front-end 126 to process data and/or signals associated with the communicating of data by the computing device 102 over an antenna 130. The baseband modem 122 may be implemented as a system-on-chip (SoC) that provides a digital communication interface for data, voice, messaging, and other applications of the computing device 102. The baseband modem 122 may also include baseband circuitry to perform high-rate sampling processes that can include analog-to-digital conversion, digital-to-analog conversion, gain correction, skew correction, frequency translation, and so forth.

The RF transceiver 124 includes circuitry and logic for frequency conversion, which may include an upconverter and/or a downconverter that perform frequency conversion in a single conversion step, or through multiple conversion steps. In some cases, components of the RF transceiver 124 are implemented as separate receiver and transmitter entities. The RF transceiver 124 may include logic to perform in-phase/quadrature (I/Q) operations, such as synthesis, encoding, modulation, decoding, demodulation, and so forth. In some cases, the RF transceiver 124 is implemented with multiple or different sections to implement respective receiving and transmitting operations (e.g., separate transmit and receive chains).

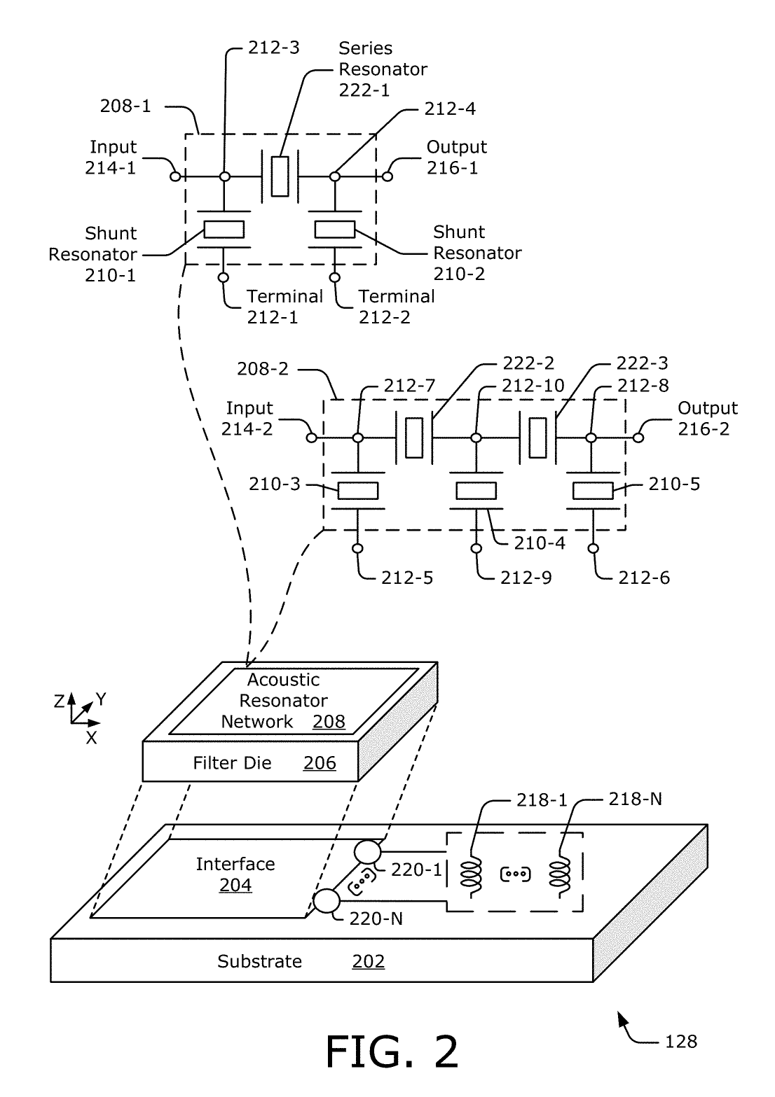

As shown, the RF front-end 126 includes at least one band-pass filter module 128. Generally, the RF front-end 126 may include switches, amplifiers, and so forth for conditioning signals that are received via the antenna 130 or signals that are to be transmitted via the antenna 130. The band-pass filter module 128, which is described with reference to FIG. 2, can at least partially implement signal filtering using magnetic coupling.

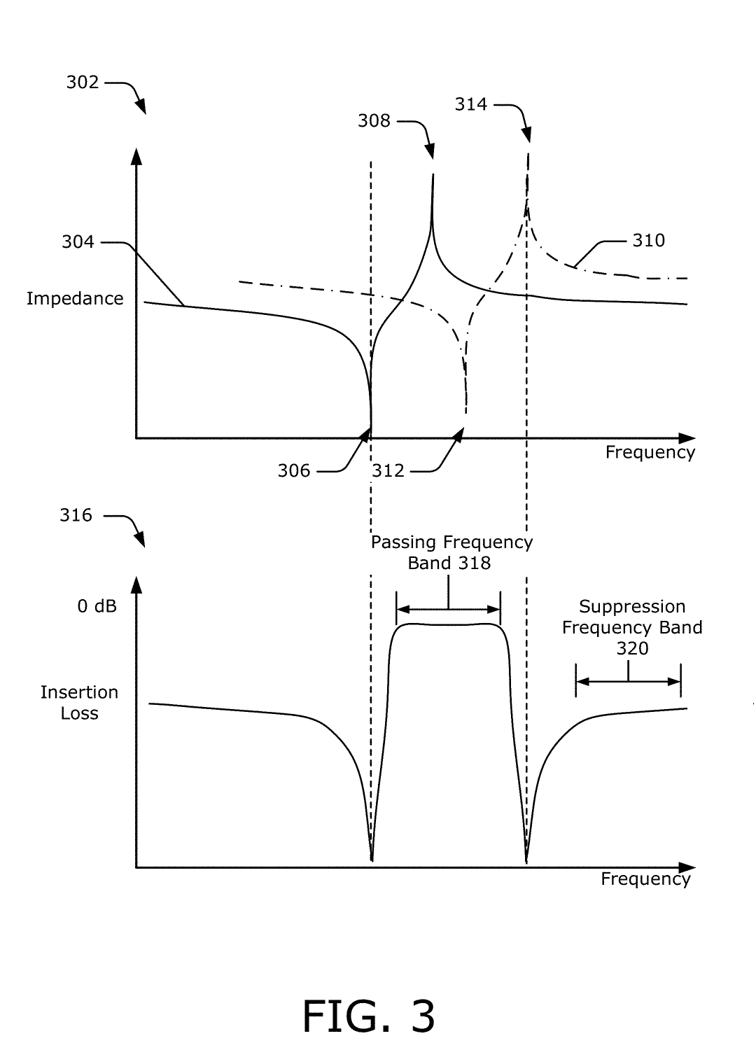

FIG. 2 illustrates an example band-pass filter module 128. The band-pass filter module 128 includes a substrate 202. In some implementations, the substrate 202 includes a laminate or multiple laminate layers that enable components of the band-pass filter module 128 to be embedded within the substrate 202. The substrate 202 also includes at least one interface 204, multiple inductors 218-1 to 218-N, and multiple connectors 220-1 to 220-N. The variable “N” is used herein to represent a same or a different positive integer for each component. A first inductor 218-1 and a second inductor 218-2 (not explicitly shown in FIG. 2) are supported by the substrate 202 and are respectively connected to a first connector 220-1 and a second connector 220-2 (not explicitly shown in FIG. 2). As used herein, the term “connect” or “connected” refers to an electrical connection, including a direct connection (e.g., connecting discrete circuit elements via a same node) or an indirect connection (e.g., connecting discrete circuit elements via one or more other devices or other discrete circuit elements). The multiple connectors 220-1 to 220-N can also be known as connection terminals. Although two inductors and two connectors are explicitly depicted, more than two of either or both may be implemented. Examples of the connectors and the inductors are described further below after FIG. 3. The interface 204, which is disposed on a surface of the substrate 202, is configured to accept and connect to a filter die 206 that includes an acoustic resonator network 208.

The acoustic resonator network 208 includes resonators (e.g., acoustic resonators), such as surface acoustic wave (SAW) resonators or bulk-acoustic wave (BAW) resonators. Two example acoustic resonator networks 208-1 and 208-2 are shown, with each including an input 214, an output 216, at least one series resonator 222, and at least one parallel or shunt resonator 210. The example acoustic resonator network 208-1 includes an input 214-1, an output 216-1, and a series resonator 222-1 connected between a first shunt resonator 210-1 and a second shunt resonator 210-2. The first shunt resonator 210-1 is connected to a first terminal 212-1, and the second shunt resonator 210-2 is connected to a second terminal 212-2. The first shunt resonator 210-1 and the second shunt resonator 210-2 are respectively connected to the series resonator 222-1 at a third terminal 212-3 and at a fourth terminal 212-4. The acoustic resonator network 208 can also be configured as a higher-order filter having multiple series resonators 222-1 to 222-N and multiple shunt resonators 210-1 to 210-N. An example higher order filter is illustrated as acoustic resonator network 208-2. This example ladder structure includes an input 214-2, an output 216-2, and at least two series resonators 222-2 to 222-3 connected together in series, as well as at least two shunt resonators, with three shunt resonators 210-3 to 210-5 depicted. Other configurations can also be used to realize the acoustic resonator network 208 so as to have at least one series resonator 222 and at least one shunt resonator 210.

In example implementations, the acoustic resonator network 208 is configured as a band-pass filter. Thus, the acoustic resonator network 208 can pass a communication signal having a communication frequency within a passing frequency band and attenuate another signal having a frequency within a suppression frequency band. The other signal may be, for instance, a spurious signal (e.g., an undesired signal) that is a harmonic or intermodulation product that results from operation of the RF transceiver 124 or the RF front-end 126 (of FIG. 1). Alternatively, the other signal can be a different communication signal associated with a different passing frequency band of another band-pass filter module or a signal associated with noise resulting from an external environment or from within the computing device 102.

Through the interface 204, the acoustic resonator network 208 receives an input signal at the input 214. The input signal can include multiple components associated with different frequencies. For example, the input signal can include a communication component having a frequency within the passing frequency band and another component having a frequency within the suppression frequency band. These components are referred to herein as a communication signal and another signal, respectively. At the output 216, the acoustic resonator network 208 generally provides the communication signals having frequencies within the passing frequency band but excludes (e.g., filters) the other signals having frequencies within the suppression frequency band. In some implementations, the acoustic resonator network 208 can operate symmetrically and therefore filter signals received via the output 216.

FIG. 3 illustrates graphs that characterize an example performance of the acoustic resonator network 208. An example impedance graph 302 depicts an impedance of the acoustic resonator network 208 over different frequencies. An impedance 304 associated with the shunt resonators of the acoustic resonator network 208 is shown having a resonant frequency 306 and an anti-resonant frequency 308. An impedance 310 associated with the series resonator of the acoustic resonator network 208 is shown having a resonant frequency 312 and an anti-resonant frequency 314.

Based on the impedance graph 302, an example frequency response graph 316 illustrates the resulting band-pass filter behavior of the acoustic resonator network 208 over different frequencies. Although the frequency response graph 316 illustrates the acoustic resonator network 208 as having an insertion loss in terms of negative decibels (e.g., less than 0 dB), it is understood that the negative decibels represent a decrease in amplitude and that the insertion loss is with respect to a magnitude (e.g., an absolute value). Accordingly, the insertion loss is smallest at 0 dB and greater at larger negative decibels.

As shown in the frequency response graph 316, an insertion loss of the acoustic resonator network 208 is less for the passing frequency band 318 as compared to other frequencies outside the passing frequency band 318, such as the insertion loss for the suppression frequency band 320. The insertion loss of the acoustic resonator network 208 is dependent upon the impedance 304 and the impedance 310. For example, at the resonant frequency 306, the insertion loss of the acoustic resonator network 208 is large because the impedance 304 of the shunt resonators is small. The small impedance of the shunt resonators causes a majority of the signal to be diverted away from the output 216, thereby increasing attenuation of the signal at the output 216. In contrast, between the resonant frequency 306 and the anti-resonant frequency 314, the insertion loss is small because the impedance 304 of the shunt resonators is large and the impedance 310 of the series resonators is small.

In general, a difference between the resonant frequency 306 and the anti-resonant frequency 308 of the shunt resonators, and similarly the difference between the resonant frequency 312 and the anti-resonant frequency 314 of the series resonators, corresponds to approximately half of a bandwidth of the band-pass filter module 128. In other words, the bandwidth is dependent upon the anti-resonant frequencies and the resonant frequencies. In some implementations, an impedance that is connected in parallel to the resonators can cause the difference between the anti-resonant frequencies and the resonant frequencies to change. For example, an inductor that is connected in parallel with a resonator can cause the difference between the anti-resonant frequency and the resonant frequency of the resonator to increase. As another example, a capacitor that is connected in parallel with a resonator can cause the difference between the anti-resonant frequency and the resonant frequency of the resonator to decrease.

Although the attenuation may be higher for the suppression frequency band 320 as compared to the passing frequency band 318, the attenuation for the suppression frequency band 320 may not be sufficient to meet cross-isolation specifications of the computing device 102. Thus, by itself, the acoustic resonator network 208 may be unable to provide sufficient attenuation at the suppression frequency band 320 for the band-pass filter module 128. For example, the acoustic resonator network 208 may provide up to approximately 50 dB of attenuation for the suppression frequency band whereas the band-pass filter module 128 is responsible for providing, or is expected to provide, more than 50 dB of attenuation, such as at least 55 dB, for the suppression frequency band.

Returning to FIG. 2, the interface 204 includes the multiple connectors 220-1 to 220-N and additional connectors that can connect to the multiple terminals 212-1 to 212-N of the acoustic resonator network 208, including some internal terminals (e.g., a tenth terminal 212-10 of the acoustic resonator network 208-2), some external terminals (e.g., the input 214-1, the output 216-1, or the first terminal 212-1 of the acoustic resonator network 208-1), some terminals that are co-positioned with the input 214 or the output 216 (e.g., the third terminal 212-3 or the fourth terminal 212-4 of the acoustic resonator network 208-1), and so forth. Through these connectors, the interface 204 can pass electrical signals between components on the substrate 202 and the acoustic resonator network 208 that is on the filter die 206. The interface 204, for example, can connect the first inductor 218-1 and the second inductor 218-2 to the acoustic resonator network 208 via the first connector 220-1 and the second connector 220-2. In some implementations, the interface 204 can connect the first connector 220-1 to the first shunt resonator 210-1 via the first terminal 212-1 or via the third terminal 212-3. Additionally, the interface 204 can connect the second connector 220-2 to the second shunt resonator 210-2 via the second terminal 212-2 or via the fourth terminal 212-4. In other words, the multiple inductors 218-1 to 218-N can be connected in series or in parallel with the multiple shunt resonators 210-1 to 210-N.

The interface 204 can additionally or alternatively connect some of the multiple terminals 212-1 to 212-N to ground. For example, the interface 204 can ground the first terminal 212-1 and the second terminal 212-2 if the first inductor 218-1 and the second inductor 218-2 are respectively connected to the third terminal 212-3 and the fourth terminal 212-4. As another example, for the acoustic resonator network 208-2, the interface 204 can connect a ninth terminal 212-9 to ground if the first inductor 218-1 and the second inductor 218-2 are respectively connected to a fifth terminal 212-5 and a sixth terminal 212-6.

The multiple inductors 218-1 to 218-N are configured to increase the attenuation for the suppression frequency band 320 based on individual inductances of the multiple inductors 218-1 to 218-N. For example, the multiple inductors 218-1 to 218-N can cause the attenuation provided by the band-pass filter module 128 to be increased by approximately five decibels or more. Additionally, the multiple inductors 218-1 to 218-N can increase the attenuation across multiple suppression frequency bands. The individual inductances can be similar or different across the multiple inductors 218-1 to 218-N.

In example implementations, the individual inductors are configured to magnetically couple with each other and to generate a mutual inductance. The mutual inductance enables the multiple inductors 218-1 to 218-N to induce a compensation impedance, which is described in further detail below. A reference polarity of a voltage induced by the mutual inductance can be positive or negative, depending on the configuration of the multiple inductors 218-1 to 218-N. The mutual inductance “M” is represented in Equation 1 below:

M=k\sqrt{L1L2}, Equation 1

where “L1” is an inductance of the first inductor 218-1, “L2” is an inductance of the second inductor 218-2, and “k” is a coupling coefficient that can have a value between zero and one.

The coupling coefficient k can vary, for example, based on a distance between the multiple inductors 218-1 to 218-N, a relative physical orientation of the multiple inductors 218-1 to 218-N, and so forth. In some example implementations, the inductors are configured to have a coupling coefficient of at least 0.2. The distance between the multiple inductors 218-1 to 218-N can be established with respect to a distance between respective centers of the inductors. This distance can be sufficiently small to provide a desired mutual inductance. In some example implementations, the first inductor 218-1 and the second inductor 218-2 can be positioned within a distance that is less than approximately 300 micrometers (μm). In other implementations, portions of the multiple inductors 218-1 to 218-N can overlap to achieve the desired mutual inductance, as described in further detail below. One or more of these various example implementations can be realized separately or jointly in any combination. Thus, two inductors can be positioned so as to be overlapping while still having a separation distance (e.g., that is based on respective centers of respective inductors) that would independently generate a mutual inductance.

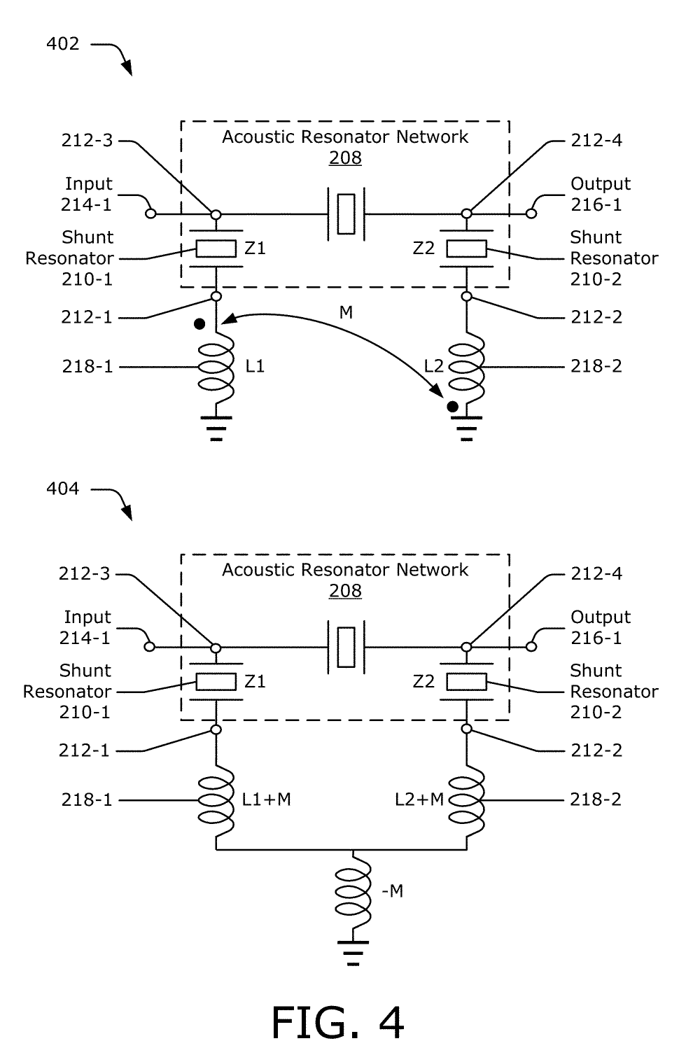

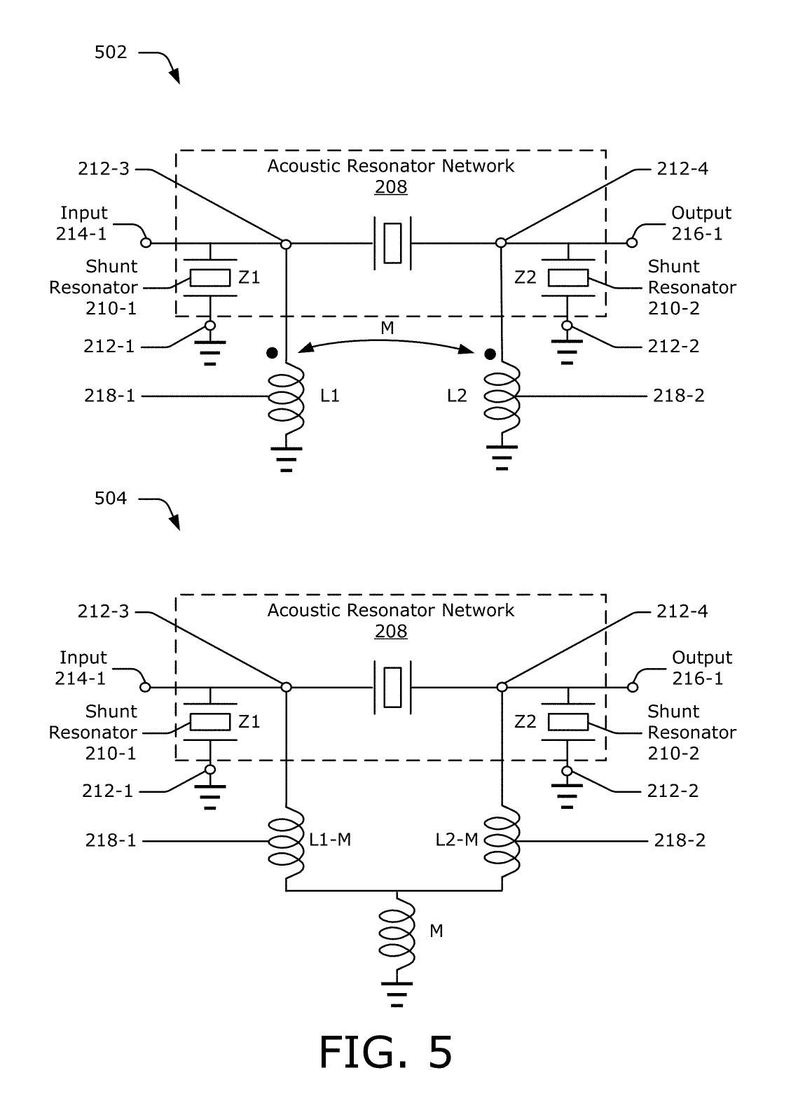

Different example circuit configurations for connecting the multiple inductors 218-1 to 218-N to the acoustic resonator network 208 to implement signal filtering using magnetic coupling are further described with respect to FIG. 4 and FIG. 5. Although FIG. 4 and FIG. 5 illustrate an acoustic resonator network 208 implemented as the first example acoustic resonator network 208-1, the described concepts and techniques can be applied to other acoustic resonator networks, such as the second example acoustic resonator network 208-2.

FIG. 4 illustrates an example implementation of the band-pass filter module 128 using series-connected inductors. In the depicted circuit 402, respective inductors of the multiple inductors 218-1 to 218-N are connected in series to respective shunt resonators 210-1 to 210-N of the acoustic resonator network 208. The first inductor 218-1 is connected to ground and to the first shunt resonator 210-1 via the first terminal 212-1. Similarly, the second inductor 218-2 is connected to ground and to the second shunt resonator 210-2 via the second terminal 212-2. Individual inductances of the first inductor 218-1 and the second inductor 218-2 are represented by “L1” and “L2”, respectively. A mutual inductance of the first inductor 218-1 and the second inductor 218-2 is represented by “M”. In the depicted configuration, the reference polarity of the voltage induced by the mutual inductance is negative. Individual impedances of the first shunt resonator 210-1 and the second shunt resonator 210-2 are represented by “Z1” and “Z2,” respectively. The individual impedances of the first shunt resonator 210-1 and the second shunt resonator 210-2 can be similar or different.

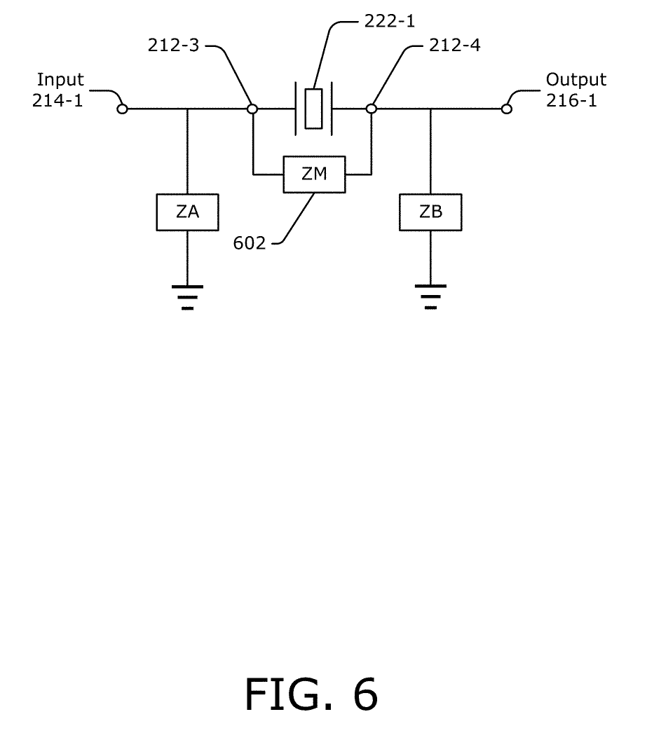

An equivalent circuit 404 is shown for the series-connected configuration described above. In the equivalent circuit 404, the mutual inductance is represented by another inductor having an equivalent inductance of “−M” and connected between ground and a node to which the first inductor 218-1 and the second inductor 218-2 are jointly connected. The equivalent inductances of the first inductor 218-1 and the second inductor 218-2 are “L1+M” and “L2+M,” respectively. A resulting wye (Y) (e.g., tee (T)) network includes the first shunt resonator 210-1, the first inductor 218-1, the second shunt resonator 210-2, the second inductor 218-2, and the mutual inductance. By applying a wye-delta (Y-Δ) transformation (e.g., a T-π transformation), the compensation impedance induced between the third terminal 212-3 and the fourth terminal 212-4 can be determined, as described in further detail below with respect to FIG. 6.

FIG. 5 illustrates an example implementation of the band-pass filter module 128 using parallel-connected inductors. In the depicted circuit 502, respective inductors of the multiple inductors 218-1 to 218-N are connected in parallel to respective shunt resonators 210-1 to 210-N of the acoustic resonator network 208. The first inductor 218-1 is connected to ground and to the first shunt resonator 210-1 via the third terminal 212-3. Similarly, the second inductor 218-2 is connected to ground and to the second shunt resonator 210-2 via the fourth terminal 212-4. Individual inductances of the first inductor 218-1 and the second inductor 218-2 are represented by “L1” and “L2,” respectively. A mutual inductance of the first inductor 218-1 and the second inductor 218-2 is represented by “M.” In the depicted configuration, the reference polarity of the voltage induced by the mutual inductance is positive. Individual impedances of the first shunt resonator 210-1 and the second shunt resonator 210-2 are represented by “Z1” and “Z2, ” respectively. The individual impedances of the first shunt resonator 210-1 and the second shunt resonator 210-2 can be similar or different.

An equivalent circuit 504 is shown for the parallel-connected configuration described above. In the equivalent circuit 504, the mutual inductance is represented by another inductor having an equivalent inductance of “M” and connected between ground and a node to which the first inductor 218-1 and the second inductor 218-2 are jointly connected. The equivalent inductances of the first inductor 218-1 and the second inductor 218-2 are “L1−M” and “L2−M,” respectively. A resulting wye (Y) (e.g., tee (T)) network includes the first inductor 218-1, the second inductor 218-2, and the mutual inductance. By applying the wye-delta (Y-α) transformation (e.g., a T-π transformation), the compensation impedance induced between the third terminal 212-3 and the fourth terminal 212-4 can be determined, as described in further detail below with respect to FIG. 6.

Other implementations of the magnetically-coupled inductors and the acoustic resonator network are also considered. For example, the series-connected inductors in FIG. 4 can be configured such that the mutual inductance induces a positive polarity voltage instead of a negative polarity voltage. As another example, the parallel-connected inductors in FIG. 5 can be configured such that the mutual inductance induces a negative polarity voltage instead of a positive polarity voltage. Furthermore, depending on which terminals of the acoustic resonator network the magnetically-coupled inductors are connected to, the compensation impedance can be connected in parallel to different portions of the acoustic resonator network 208 (such as between the third terminal 212-3 and the sixth terminal 212-6 in the example second acoustic resonator network 208-2). In some implementations, the multiple inductors 218-1 to 218-N can include more than two inductors, with some or all of the multiple inductors 218-1 to 218-N being magnetically-coupled. In other implementations, a combination of series-connected inductors and parallel-connected inductors can be used.

FIG. 6 illustrates a compensation impedance 602 “ZM” for signal filtering using magnetic coupling. Equivalent impedances of a delta network resulting from the wye-delta transformation of FIG. 4 and FIG. 5 are represented by “ZA,” “ZB,” and “ZM”. For the example implementation of FIG. 5, the first shunt resonator 210-1 and the second shunt resonator 210-2 are in parallel with “ZA” and “ZB,” respectively (not shown). The compensation impedance 602, which is induced by the mutual inductance of the inductors, is connected to the third terminal 212-3 and the fourth terminal 212-4. Thus, the compensation impedance 602 is connected in parallel with a portion of the acoustic resonator network 208 (e.g., one or more resonators of the acoustic resonator network 208 that are connected between the third terminal 212-3 and the fourth terminal 212-4). In the depicted configuration, the compensation impedance 602 is in parallel with the series resonator 222-1. As described above, a parallel impedance, such as the compensation impedance 602, can cause a change in a difference between the resonant frequency 312 and the anti-resonant frequency 314 of the series resonator 222-1.

The compensation impedance 602 is based on the mutual inductance and frequency of the signals received via the input 214. The compensation impedance 602 can adjust the anti-resonant frequency and the resonant frequency associated with the resonators. This results in the compensation impedance 602 adjusting the bandwidth or the insertion loss of the band-pass filter module 128. For example, if the compensation impedance 602 is configured to act as an inductor (e.g., as having a reactance that is proportional to frequency), the bandwidth of the band-pass filter module 128 can increase and the insertion loss for the passing frequency band 318 can decrease. Likewise, if the compensation impedance 602 is configured to act as a capacitor (e.g., as having a reactance that is inversely proportional to frequency), the bandwidth of the band-pass filter module 128 can decrease and the insertion loss for the passing frequency band 318 can increase. In some cases, the compensation impedance 602 can be configured to act as an inductor at some frequencies and as a capacitor at other frequencies.

The compensation impedance 602 facilitates attenuating signals within the suppression frequency band and passing signals within the passing frequency band. In general, the compensation impedance 602 can compensate for a change in the band-pass filter module 128's bandwidth, such as changes that result from the multiple inductors 218-1 to 218-N being connected to the acoustic resonator network 208. In some implementations, the connecting of the multiple inductors 218-1 to 218-N to the acoustic resonator network 208 may increase insertion loss at a lower-band edge of the passing frequency band 318 due to individual inductances of the multiple inductors 218-1 to 218-N. The increase of the insertion loss can cause the bandwidth of the band-pass filter module 128 to decrease. However, by magnetically coupling the inductors, the compensation impedance 602 can be generated so that the resulting insertion loss and bandwidth meet the in-band specifications. The improvement of the insertion loss may be, for example, on the order of approximately 0.15 dB, as compared to non-magnetically coupled inductors.

By using inductors that can further attenuate signals for the suppression frequency band 320 without significantly increasing the insertion loss for the passing frequency band 318, the band-pass filter module 128 can accommodate both insertion loss and cross-isolation performance specifications. Additionally, the compensation impedance can improve an adjacent channel leakage ratio (ACLR) of the computing device 102 by reducing a variation of the impedance associated with the band-pass filter module 128 across different frequencies.

For the series-connected inductors depicted in FIG. 4, the compensation impedance is represented in Equation 2 below. For mathematical simplicity, Equation 2 assumes that the two inductors have a same inductance (L=L1=L2) and that the two shunt resonators have a same impedance (Zres=Z1=Z2). Furthermore, the impedance of the shunt resonators are approximated as a capacitance as the compensation impedance 602 can be evaluated at frequencies different than a resonant frequency of the two shunt resonators (Zres=1/jωCres). Additionally, the polarity of the voltage induced by the mutual inductance is assumed to be negative, as depicted in FIG. 4.

$$ZM = \frac{\frac{1}{- {ω}^{2} {Cres}^{2}} + {ω}^{2} ( {M}^{2} - {L}^{2} ) + \frac{2 L}{Cres}}{- j ω M} \qquad Equation 2$$

The compensation impedance 602 can be further simplified by assuming Cres is on the order of picofarads (pF) and the inductance L is on the order of nanohenries (nH), thus

$${ω}^{2} ( {M}^{2} - {L}^{2} ) << \frac{1}{- {ω}^{2} {Cres}^{2}} and \frac{2 L}{Cres} .$$

The resulting simplified compensation impedance is shown in Equation 3 below.

$$ZM = \frac{\frac{2 L1}{{Cres}^{2}} - \frac{1}{{ω}^{2} {Cres}^{2}}}{- j ω M} \qquad Equation 3$$

As seen in Equation 3, the compensation impedance 602 “ZM” depends on both frequency “ω” and mutual inductance “M”. Additionally, the compensation impedance 602 acts as an inductor when

$$Cres > \frac{1}{2 L {ω}^{2}}$$

or as a capacitor when

$$Cres < \frac{1}{2 L {ω}^{2}} .$$

On the other hand, if the multiple inductors 218-1 to 218-N are configured such that the mutual inductance induces a positive polarity voltage, the compensation impedance 602 acts as an inductor when

$$Cres < \frac{1}{2 L {ω}^{2}}$$

or as a capacitor when

$$Cres > \frac{1}{2 L {ω}^{2}} .$$

For the parallel-connected inductors depicted in FIG. 5, the compensation impedance is represented in Equation 4 below. For mathematical simplicity, Equation 4 assumes that the two inductors have a same inductance (L=L1=L2). Additionally, the polarity of the voltage induced by the mutual inductance is assumed to be positive, as depicted in FIG. 5.

$$ZM = \frac{j ω ( {L}^{2} - {M}^{2} )}{M} \qquad Equation 4$$

As seen in Equation 4, the compensation impedance 602 “ZM” depends on both frequency “ω” and mutual inductance “M”. Additionally, the compensation impedance 602 acts as an inductor.

As shown in Equation 3 and Equation 4, the compensation impedance 602 “ZM” can be tuned by the mutual inductance, the inductance of the inductors, or the voltage polarity that is induced by the mutual inductance.

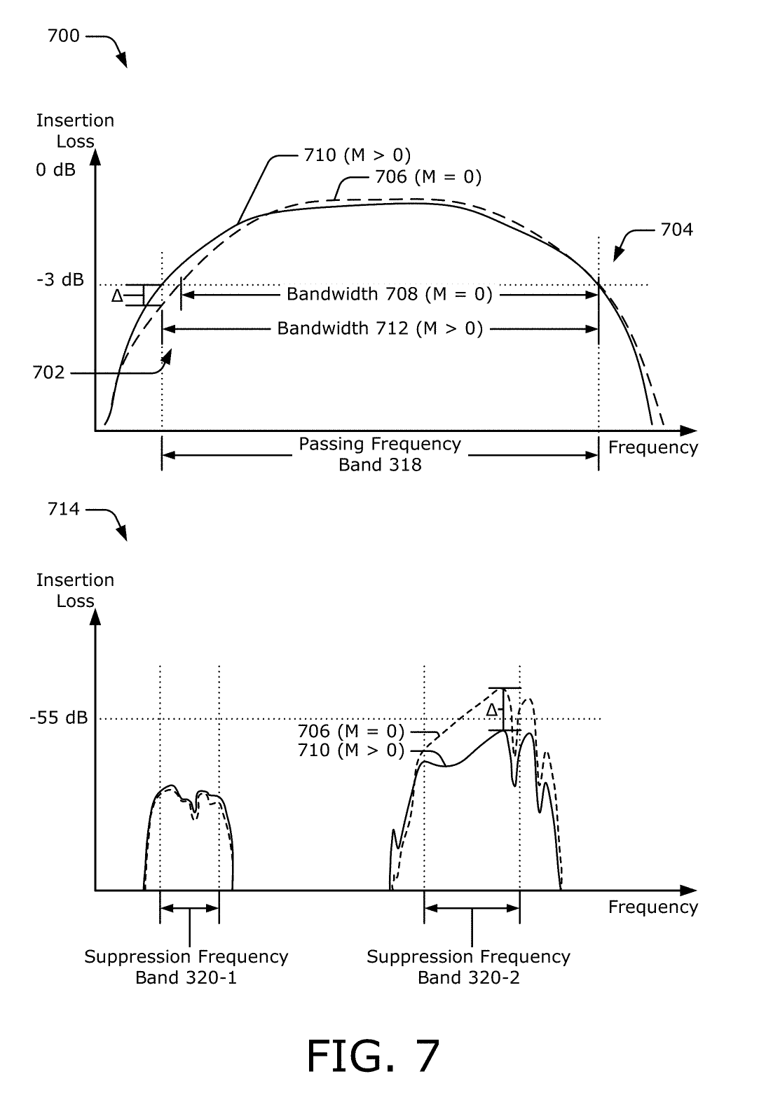

FIG. 7 illustrates graphs depicting example performance differences associated with non-magnetically coupled and magnetically-coupled inductors in the band-pass filter module 128. A first example frequency response graph 700 illustrates the performance of the band-pass filter module 128 across the passing frequency band 318. A bandwidth of the band-pass filter module 128 is established by a lower cut-off frequency 702 and an upper cut-off frequency 704. The lower cut-off frequency 702 and the upper cut-off frequency 704 define a range of frequencies at which the insertion loss is less than or equal to 3 dB. A second example frequency response graph 714 illustrates the performance of the band-pass filter module 128 across a first suppression frequency band 320-1 and a second suppression frequency band 320-2. As an example, the passing frequency band 318 can refer to a transmitting frequency band used for an uplink, such as frequency band 2 that includes frequencies between 1850 and 1910 MHz, the first suppression frequency band 320-1 can refer to a receiving frequency band used for a downlink, such as frequency band 2 that includes frequencies between 1930 and 1990 MHz, and the second suppression frequency band 320-2 can refer to another receiving frequency band that can also be used for a downlink, such as frequency band 66 that includes frequencies between 2110 and 2200 MHz.

If the multiple inductors 218-1 to 218-N that are connected to the acoustic resonator network 208 have no magnetic coupling (e.g., the mutual inductance M is zero), the corresponding compensation impedance 602 acts like an open circuit. Consequently, the multiple inductors 218-1 to 218-N are unable to compensate for an increase in the insertion loss caused by connecting the individual inductances of the multiple inductors 218-1 to 218-N to the acoustic resonator network 208. In the depicted example, the insertion loss increases at a lower-band edge of the passing frequency band 318, thus causing the lower cut-off frequency 702 to increase. In some cases, the increase in the insertion loss can be approximately 0.4 dB and the increase in the lower cut-off frequency 702 can be approximately 2 MHz. The resulting response of the band-pass filter module 128 is shown by a dashed line 706 along with an associated bandwidth 708. As illustrated in the first example frequency response graph 700, the lower cut-off frequency 702 is higher than a lower-band edge of the passing frequency band 318. As a result, communication signals having frequencies at or near the lower-band edge of the passing frequency band 318 experience higher insertion loss than communication signals having frequencies between the lower cut-off frequency 702 and the upper cut-off frequency 704. Additionally, in the second example frequency response graph 714, the insertion loss of the band-pass filter module 128, for example, is less than 55 dB within the second suppression frequency band 320-2. Thus, spurious signals having frequencies at or near the suppression frequency band 320-2 may not be adequately attenuated.

In contrast, if the multiple inductors 218-1 to 218-N that are connected to the acoustic resonator network 208 are magnetically-coupled (e.g., the mutual inductance M is greater than zero) as described herein for implementations of signal filtering using magnetic coupling, the compensation impedance 602 can compensate for the change to the insertion loss and bandwidth that is associated with connecting the multiple inductors 218-1 to 218-N to the acoustic resonator network 208. For example, by using series-connected inductors that induce a negative polarity voltage, as shown in FIG. 4, the compensation impedance 602 can act as an inductor and increase the bandwidth of the band-pass filter module 128, particularly for the lower-band edge. The resulting response is shown by a solid line 710, along with an associated bandwidth 712 and the resulting change to the insertion loss (Δ). As shown in the first example frequency response graph 700, the bandwidth 712 is larger than the bandwidth 708 and is at least approximately co-extensive with the passing frequency band 318. In some magnetically-coupled implementations, the insertion loss can decrease by approximately 0.15 dB within some portions of the passing frequency band 318 and the bandwidth 712 can increase by at least approximately one MHz compared to the insertion loss and the bandwidth 708 of a non-magnetically coupled implementation. Thus, the compensation impedance 602 can enable magnetically-coupled inductors to be connected to the acoustic resonator network without appreciably increasing the insertion loss of the passing frequency band 318 or decreasing the bandwidth of the band-pass filter module 128. The increase in insertion loss can be, for example, approximately less than 0.1 dB. The decrease in bandwidth can be, for example, approximately less than one MHz.

At some of the suppression frequency bands 320, the compensation impedance can act as a small capacitor and not appreciably decrease the attenuation, such as within the first suppression frequency band 320-1. Additionally or alternatively, at other suppression frequency bands 320 the insertion loss can increase due to the mutual inductance, wherein the insertion loss can increase by, for example, at least 5 dB within the second suppression frequency band 320-2. In this way, the compensation impedance 602 facilitates passing signals within the passing frequency band 318 and attenuating signals within the suppression frequency band 320. By using multiple inductors 218-1 to 218-N that are configured to further attenuate signals at the suppression frequency bands 320 without appreciably increasing the insertion loss for the passing frequency band 318, the band-pass filter module 128 can accommodate both insertion-loss and cross-isolation performance specifications.

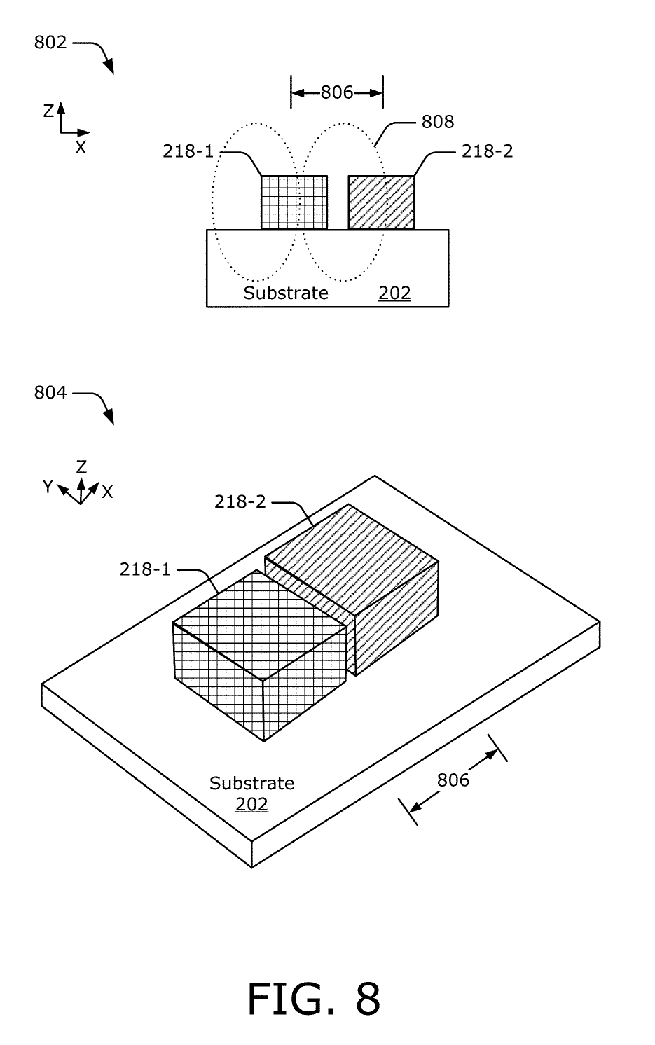

FIGS. 8-10 illustrate example implementations of the multiple inductors 218-1 to 218-N for signal filtering using magnetic coupling. The multiple inductors 218-1 to 218-N can be realized using surface-mount devices (SMDs), embedded inductors, or a combination of both. Although two inductors are illustrated in FIGS. 8-10, the example implementations can be extended for implementations including more than two inductors.

FIG. 8 illustrates an example implementation having two surface-mount inductors (SMDs) for signal filtering using magnetic coupling. A cross-sectional view 802 depicts the first inductor 218-1 and the second inductor 218-2 as surface-mount inductors that are disposed on the surface of the substrate 202. The inductors are also illustrated via a three-dimensional perspective view 804. The mutual inductance of the first inductor 218-1 and the second inductor 218-2 can be based on a distance 806 between the first inductor 218-1 and the second inductor 218-2. The distance 806 can be established as a distance between a center of the first-inductor 218-1 and a center of the second inductor 218-2. In the depicted illustration, the distance 806 enables a magnetic flux 808 caused by a current flowing through the first inductor 218-1 to induce a voltage in the second inductor 218-2. In some implementations, the distance 806 is on the order of micrometers (μm), such as less than approximately 300 μm. The use of SMDs enable the first inductor 218-1 or the second inductor 218-2 to be replaced in an alternative design with another inductor having a different inductance. The replacement can enable the attenuation of the suppression frequency band 320 to be adjusted, even after some fabrication has been completed.

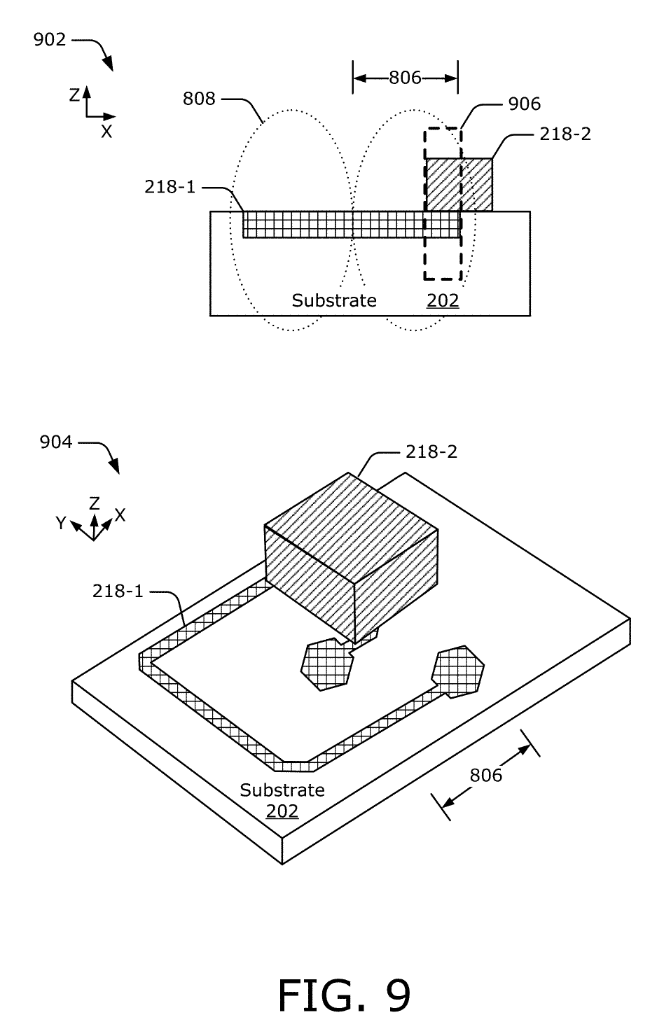

FIG. 9 illustrates an example implementation having one surface-mount inductor and one embedded inductor for signal filtering using magnetic coupling. A cross-sectional view 902 depicts the first inductor 218-1 as an embedded inductor and the second inductor 218-2 as a surface-mount inductor. The inductors are also illustrated via a three-dimensional perspective view 904. The embedded inductor can be realized by using a substrate 202 that includes, for example, at least one laminate layer and embedding the first inductor 218-1 in the laminate layer (e.g., as a printed coil). If the substrate 202 includes multiple laminate layers, the embedded inductor can also be realized by embedding the first inductor 218-1 across the multiple laminate layers (not shown in FIG. 9). The mutual inductance of the first inductor 218-1 and the second inductor 218-2 can be based on the distance 806 between the first inductor 218-1 and the second inductor 218-2. In the depicted illustration, the distance 806 enables the magnetic flux 808 caused by a current flowing through the first inductor 218-1 to induce a voltage in the second inductor 218-2.

In some implementations, at least a portion of the second inductor 218-2 overlaps the first inductor 218-1 along a vertical dimension that is substantially perpendicular to the surface of the substrate (e.g., a vertical dimension that is represented by the z-axis). Overlap 906 identifies an overlapping portion of the first inductor 218-1 and an overlapping portion of the second inductor 218-2. By using a combination of inductors including an embedded inductor and a surface-mount inductor, the mutual inductance can be better-controlled and fine-tuned to provide the desired compensation impedance. Furthermore, in an alternative design, the surface-mount inductor can be replaced with another inductor having a different inductance to adjust the attenuation of the suppression frequency band 320, even after at least partial fabrication. Further, having at least one embedded inductor can decrease a minimum size of the distance 806. Additionally, the use of at least one embedded inductor can decrease costs associated with the band-pass filter module 128 and conserve space on the surface of the substrate 202.

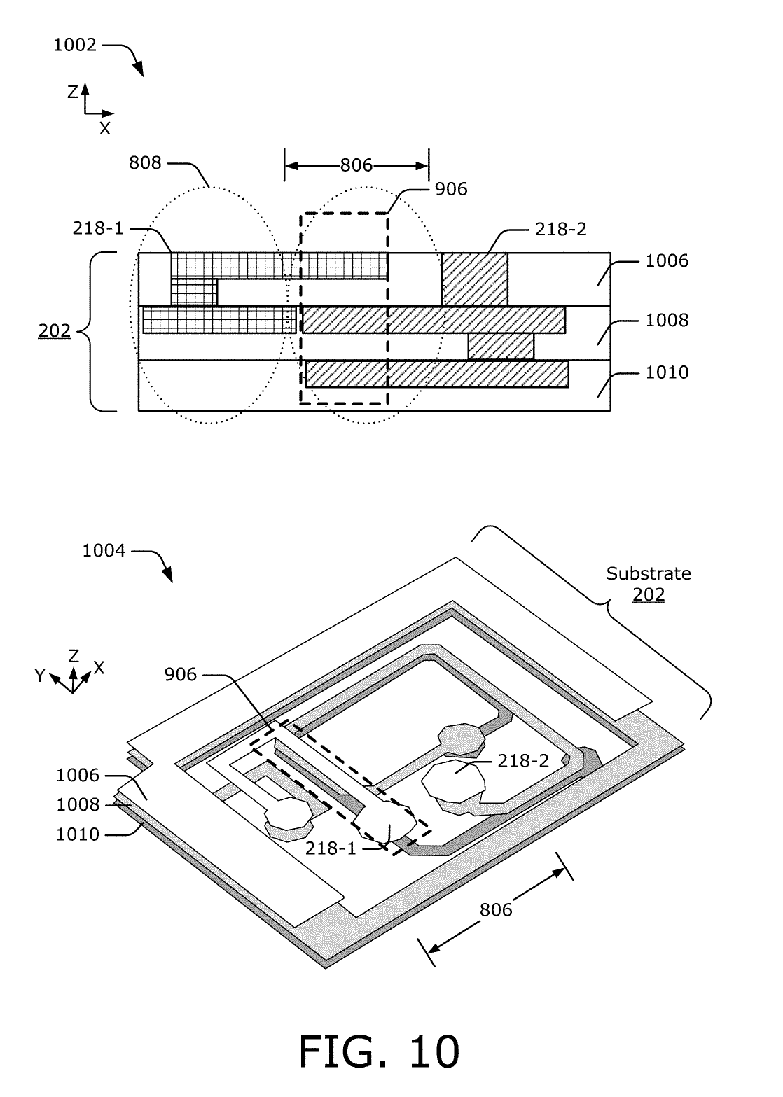

FIG. 10 illustrates an example implementation having two embedded inductors for signal filtering using magnetic coupling. A cross-sectional view 1002 depicts the first inductor 218-1 and the second inductor 218-2 as embedded inductors. The inductors are also illustrated via a three-dimensional perspective view 1004. In the depicted illustration, the substrate 202 includes multiple laminate layers, such as an upper layer 1006, a middle layer 1008, and a lower layer 1010. The first inductor 218-1 and the second inductor 218-2 are embedded in the multiple laminate layers (e.g., jointly disposed across the multiple laminate layers). The mutual inductance of the first inductor 218-1 and the second inductor 218-2 can be based on the distance 806 between the first inductor 218-1 and the second inductor 218-2. In the depicted illustration, the distance 806 enables the magnetic flux 808 caused by a current flowing through the first inductor 218-1 to induce a voltage in the second inductor 218-2.

In some implementations, at least a portion of the second inductor 218-2 overlaps at least a portion of the first inductor 218-1 along a vertical dimension that is substantially perpendicular to the surface of the substrate (e.g., a dimension as represented by the z-axis). This is illustrated by a portion of the first inductor 218-1 being on one layer of the multiple laminate layers (e.g., the upper layer 1006) and overlapping a portion of the second inductor 218-2 that is on another layer of the multiple laminate layers (e.g., the middle layer 1008 and the lower layer 1010). Overlap 906 identifies an overlapping portion of the first inductor 218-1 and an overlapping portion of the second inductor 218-2. By using embedded inductors, the use of SMDs can be reduced and the mutual inductance can be better-controlled so as to establish the mutual induction at a fine precision level that provides the desired compensation impedance. In addition, the use of embedded inductors can decrease costs associated with the band-pass filter module 128 and conserve space on the surface of the substrate 202.

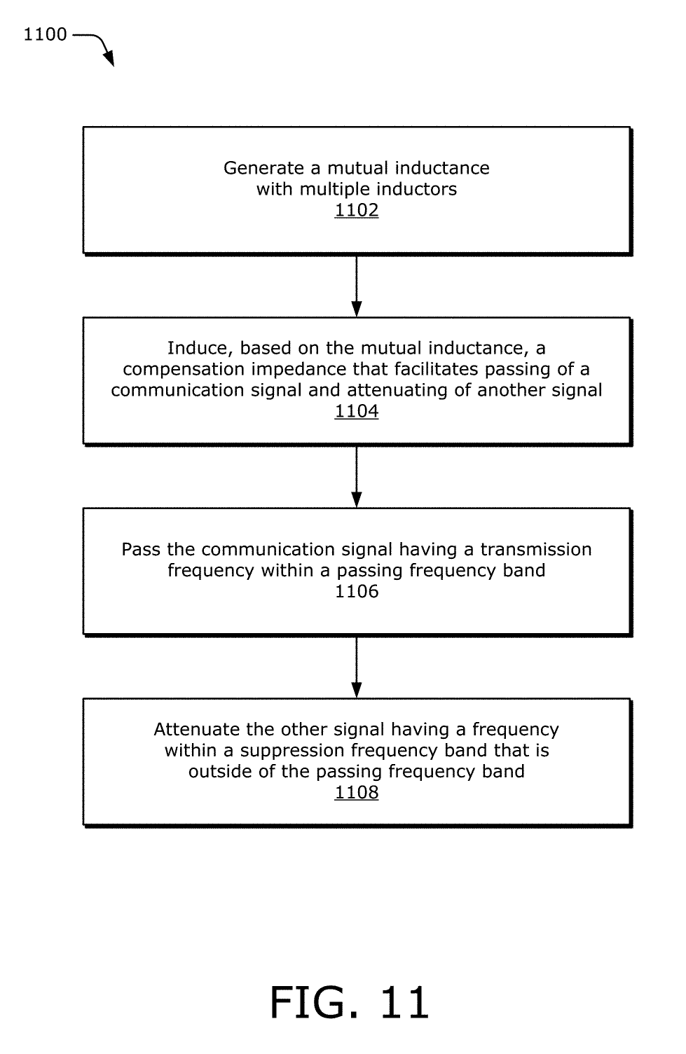

FIG. 11 is a flow diagram illustrating an example process 1100 for signal filtering using magnetic coupling. The process 1100 is described in the form of a set of blocks 1102-1108 that specify operations that can be performed. However, operations are not necessarily limited to the order shown in FIG. 11 or described herein, for the operations may be implemented in alternative orders or in fully or partially overlapping manners. Operations represented by the illustrated blocks of the process 1100 may be performed by a band-pass filter module 128 (e.g., of FIG. 1 or 2). More specifically, the operations of the process 1100 may be performed by the acoustic resonator network 208 as shown in FIG. 2 in conjunction with the multiple inductors 218-1 to 218-N as shown in FIGS. 2, 4, 5, 8, 9, and 10.

At block 1102, a mutual inductance is generated with multiple inductors. For example, the multiple inductors 218-1 to 218-N can be configured to magnetically couple with one another based at least partially on a distance between the multiple inductors 218-1 to 218-N. To do so, the multiple inductors 218-1 to 218-N can be implemented using SMDs, printed circuits, embedded inductors, or a combination thereof. In some implementations, portions of the multiple inductors 218-1 to 218-N overlap each other.

At block 1104, a compensation impedance is induced based on the mutual inductance. The compensation impedance facilitates passing of a communication signal and attenuating of another signal. For example, the compensation impedance 602 can be induced in parallel with a portion of the acoustic resonator network 208. The compensation impedance 602 can decrease an insertion loss for the passing frequency band 318 while keeping the attenuation for the suppression frequency band 320 relatively unchanged. Furthermore, by decreasing the insertion loss, the compensation impedance 602 can increase a bandwidth associated with the passing frequency band 320.

At block 1106, the communication signal having a transmission frequency within a passing frequency band is passed. For example, the acoustic resonator network 208 can be configured to pass the communication signal with a small amount of insertion loss if the communication signal is within the passing frequency band 318.

At block 1108, the other signal having a frequency within a suppression frequency band that is outside of the passing frequency band is attenuated. For example, the acoustic resonator network 208 and the multiple inductors 218-1 to 218-N can be configured to attenuate the other signal in the suppression frequency band 320. In some implementations, the attenuation can be at least approximately 55 dB.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a substrate having a surface, the substrate including:
an interface disposed on the surface, the interface including multiple connectors, the interface configured to accept a filter die that includes an acoustic resonator network; and
multiple inductors supported by the substrate and connected to the multiple connectors of the interface, the multiple inductors configured to generate a mutual inductance based on individual inductors of the multiple inductors.

2. The apparatus of claim 1, wherein:
the multiple inductors comprise a first inductor and a second inductor;
the multiple connectors comprise a first connector and a second connector;
the first inductor is connected to the first connector;
the second inductor is connected to the second connector; and
the first inductor is embedded within the substrate.

3. The apparatus of claim 2, wherein the second inductor comprises a surface-mount device that is disposed on the surface of the substrate.

4. The apparatus of claim 2, wherein the substrate comprises a laminate, and the first inductor and the second inductor are embedded in the laminate.

5. The apparatus of claim 4, wherein:
the laminate comprises multiple laminate layers; and
the first inductor is embedded in the multiple laminate layers.

6. The apparatus of claim 5, wherein:
the second inductor is embedded in the multiple laminate layers; and
a portion of the first inductor that is on one layer of the multiple laminate layers overlaps a portion of the second inductor that is on another layer of the multiple laminate layers.

7. The apparatus of claim 2, wherein:
the mutual inductance is based on a distance between the first inductor and the second inductor; and
the distance is sufficiently small such that a coupling coefficient of the mutual inductance is at least approximately 0.2.

8. The apparatus of claim 7, wherein the distance between respective centers of the first inductor and the second inductor is less than approximately 300 micrometers (μm).

9. The apparatus of claim 2, wherein:
the first connector is configured to connect the first inductor to a first shunt resonator of the acoustic resonator network; and
the second connector is configured to connect the second inductor to a second shunt resonator of the acoustic resonator network.

10. The apparatus of claim 9, wherein:
the first connector is configured to connect the first inductor in series with the first shunt resonator;
the second connector is configured to connect the second inductor in series with the second shunt resonator; and
the first inductor and the second inductor are further configured to induce a negative voltage based on the mutual inductance.

11. The apparatus of claim 9, wherein:
the first connector is configured to connect the first inductor in parallel with the first shunt resonator;
the second connector is configured to connect the second inductor in parallel with the second shunt resonator; and
the first inductor and the second inductor are further configured to induce a positive voltage based on the mutual inductance.

12. The apparatus of claim 1, further comprising:
a filter die connected to the interface, the filter die including the acoustic resonator network tuned for a passing frequency band, the acoustic resonator network configured to:
pass a communication signal having a transmission frequency within the passing frequency band; and
attenuate another signal having a frequency within a suppression frequency band, the suppression frequency band being outside of the passing frequency band,
wherein the multiple inductors are further configured to increase the attenuation of the other signal for the suppression frequency band based on individual inductances of the multiple inductors.

13. The apparatus of claim 12, wherein the multiple inductors are further configured to:
induce a compensation impedance for the acoustic resonator network based on the mutual inductance; and
increase the attenuation of the other signal in the suppression frequency band without appreciably increasing an attenuation of the communication signal for the passing frequency band using the compensation impedance.

14. The apparatus of claim 12, wherein the multiple inductors are further configured to increase the attenuation of the other signal in the suppression frequency band without appreciably decreasing a bandwidth associated with the passing frequency band.

15. The apparatus of claim 12, wherein the acoustic resonator network includes multiple resonators interconnected in a ladder structure.

16. An apparatus comprising:
a substrate having a surface;
multiple inductors supported by the substrate and configured to generate a mutual inductance based on individual inductors of the multiple inductors; and
interface means for interfacing the multiple inductors with a filter die that includes an acoustic resonator network, the interface means disposed on the surface of the substrate and including:
connection means for connecting the multiple inductors to the acoustic resonator network of the filter die.

17. The apparatus of claim 16, wherein:
the acoustic resonator network is configured to:
pass a communication signal having a transmission frequency within a passing frequency band; and
attenuate another signal having a frequency within a suppression frequency band that is outside of the passing frequency band; and
the multiple inductors are further configured to increase an attenuation for the suppression frequency band, the multiple inductors including:
means for configuring a bandwidth to be approximately co-extensive with the passing frequency band.

18. The apparatus of claim 17, wherein the means for configuring the bandwidth comprises means for inducing a compensation impedance that is formed in parallel with a portion of the acoustic resonator network.

19. The apparatus of claim 18, wherein the means for inducing the compensation impedance comprises means for generating the mutual inductance using the multiple inductors.

20. The apparatus of claim 19, wherein the compensation impedance is configured to enable the multiple inductors to increase the attenuation for the suppression frequency band without appreciably increasing an attenuation for the passing frequency band.

21. A method for signal filtering using magnetic coupling, the method comprising:
generating a mutual inductance with multiple inductors;
inducing, based on the mutual inductance, a compensation impedance that facilitates passing of a communication signal and attenuating of another signal;
passing the communication signal having a transmission frequency within a passing frequency band; and
attenuating the other signal having a frequency within a suppression frequency band that is outside of the passing frequency band.

22. The method of claim 21, wherein the inducing the compensation impedance comprises decreasing an insertion loss for the passing frequency band.

23. The method of claim 22, wherein the decreasing the insertion loss comprises increasing a bandwidth associated with the passing frequency band.

24. The method of claim 23, wherein:
the bandwidth is established by a lower cut-off frequency and an upper cut-off frequency; and
the increasing the bandwidth comprises decreasing the lower cut-off frequency.

25. An apparatus comprising:
a substrate having a surface;
a filter die mounted to the surface of the substrate, the filter die including an acoustic resonator network comprising at least one series resonator and at least two shunt resonators, the acoustic resonator network configured as a band-pass filter to provide a first amount of attenuation for a passing frequency band and a second amount of attenuation for a suppression frequency band that is outside the passing frequency band; and
at least two magnetically-coupled inductors supported by the substrate and connected to the two shunt resonators, the two magnetically-coupled inductors configured to:
increase the second amount of attenuation for the suppression frequency band; and
induce a compensation impedance that is based on a mutual inductance of the two magnetically-coupled inductors.

26. The apparatus of claim 25, wherein the compensation impedance is induced in parallel with the series resonator.

27. The apparatus of claim 25, wherein:
each respective inductor of the two magnetically-coupled inductors is connected in series with a respective shunt resonator of the two shunt resonators; and
the mutual inductance of the two magnetically-coupled inductors is configured to induce a negative polarity voltage.

28. The apparatus of claim 25, wherein:
each respective inductor of the two magnetically-coupled inductors is connected in parallel with a respective shunt resonator of the two shunt resonators; and
the mutual inductance of the two magnetically-coupled inductors is configured to induce a positive polarity voltage.

29. The apparatus of claim 25, wherein at least one inductor of the two magnetically-coupled inductors is embedded within the substrate.

30. The apparatus of claim 25, wherein the apparatus comprises a multiplexer configured to provide cross-isolation between multiple frequency bands.
